(19) United States
(12) Patent Application Publication
(10) Pub. No.: US 2026/0164604 A1
(43) Pub. Date: Jun. 11, 2026

(54) EXPANSION TANK AND COOLING SYSTEM HAVING THE SAME

(71) Applicant: Fulian Precision Electronics (Tianjin) Co., Ltd., Tianjin (CN)

(72) Inventors: CHIN-HAN CHAN, New Taipei (TW); Tsung-Lin Liu, Neihu (TW); Yu-Chia Ting, Neihu (TW); Chia-Nan Pai, Tu-Cheng (TW)

(21) Appl. No.: 18/971,456

(22) Filed: Dec. 6, 2024

(30) Foreign Application Priority Data
Oct. 21, 2024 (CN) 202411470374.X

(51) Int. Cl. H05K 7/20

(52) U.S. Cl. CPC H05K 7/20327; H05K 7/208

(57) ABSTRACT

An expansion tank is applied for a cooling system including a fluid storage tank for storing a coolant. The expansion tank includes a tank body and an adjusting member. The tank body includes an air chamber, a fluid storage chamber, a first inlet, a first outlet, a second inlet, and a second outlet. The first inlet/outlet are connected to the air chamber, and the second inlet/outlet are connected to the fluid storage chamber. The first inlet is connected to the fluid storage tank, such that the coolant enters the air chamber. The fluid storage chamber can receive the coolant after being cooled through the second inlet. The second outlet is further connected to the fluid storage tank, such that the cooled coolant is supplemented to the fluid storage tank. The adjusting member can connect the air chamber with an ambient environment.

### FIELD

The subject matter herein generally relates to cooling, and more particularly, to an expansion tank and a cooling system having the expansion tank.

### BACKGROUND

An expansion tank may be connected to a fluid storage tank through a pipeline. An interior space of the expansion tank is divided into a water chamber and an air chamber by a rubber diaphragm. When the fluid in the fluid storage tank is heated and expands, the rubber diaphragm deforms, and the air in the air chamber may be compressed to adjust the pressure in the fluid storage tank.

However, the rubber diaphragm may be broken during long-term use, such that the expansion tank cannot adjust the pressure in the fluid storage tank. Therefore, there is a room for improvement in the art.

### BRIEF DESCRIPTION OF THE DRAWINGS

Implementations of the present technology will now be described, by way of embodiment, with reference to the attached figures.

FIG. 1 is a diagrammatic view of a cooling system according to an embodiment of the present disclosure.

FIG. 2 a diagrammatic view showing portions of the cooling system of FIG. 1 in another embodiment.

FIG. 3 is a diagrammatic view of an expansion tank of the cooling system of FIG. 2.

FIG. 4 is similar to FIG. 3, but showing the expansion tank from another angle.

FIG. 5 is a diagrammatic view showing portions of the expansion tank of FIG. 3.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and members have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

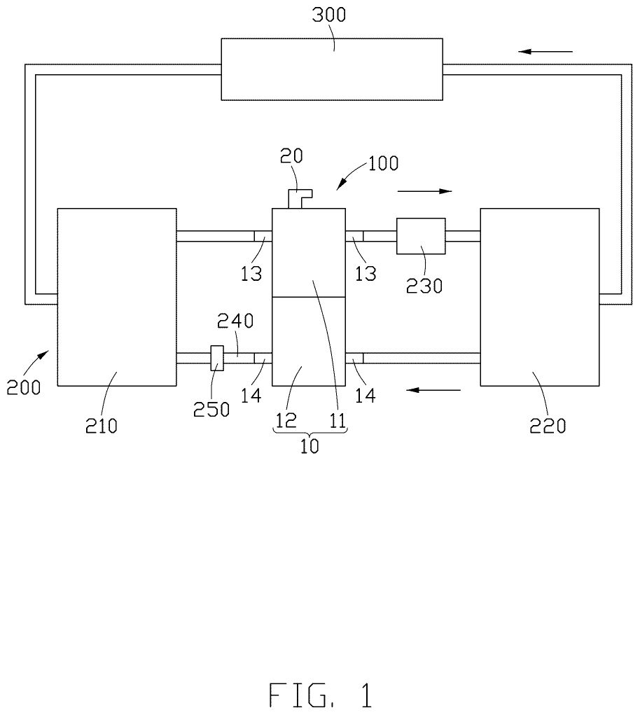

Referring to FIG. 1, a cooling system 200 is provided according to an embodiment of the present disclosure. The cooling system 200 may be connected to an electronic device such as a server system 300. The server system 300 includes a server and a refrigeration unit. When the server works and generates heat, the refrigeration unit produces a coolant that may flow through and cool the server. The coolant flowing through the server absorbs heat generated by the server, and the temperature of the coolant increases. The coolant after absorbing heat is a high-temperature coolant, which is called a first coolant hereinafter. The coolant produced by the refrigeration unit is a low-temperature coolant, which is called a second coolant hereinafter. It is understandable that the terms “first coolant” and “second coolant” refer to a same type of coolant but with different temperatures.

The cooling system 200 includes a fluid storage tank 210, a cooling tank 220, and an expansion tank 100. The fluid storage tank 210 is connected to the expansion tank 100 and used to store the coolant after absorbing heat. Since the first coolant may expand in volume, the pressure in the fluid storage tank 210 may increase. Thus, the first coolant in the fluid storage tank 210 may be forced into the expansion tank 100, thereby adjusting the pressure in the fluid storage tank 210.

The cooling tank 220 is connected to the expansion tank 100 and used to store the second coolant produced by the refrigeration unit. The cooling tank 220 may provide the second coolant to the expansion tank 100. Then, the expansion tank 100 may provide the second coolant to the fluid storage tank 210. The second coolant may cool the expansion tank 100 and the fluid storage tank 210, thereby adjusting the pressure in the fluid storage tank 210 more quickly to avoid any damage to the fluid storage tank 210 due to excessive pressure.

The expansion tank 100 includes a tank body 10 and an adjusting member 20. The tank body 10 may be substantially a cubic or cylinder structure. The tank body 10 is divided into an air chamber 11 and a fluid storage chamber 12 separated from each other. The air chamber 11 is used to receive the first coolant from the fluid storage tank 210, thereby reducing the pressure in the fluid storage tank 210. The fluid storage chamber 12 is used to store the second coolant from the cooling tank 220, thereby cooling the air chamber 11 and reducing the pressure in the air chamber 11. The adjusting member 20 is used to connect the air chamber 11 to an ambient environment, thereby adjusting the pressure in the air chamber 11. In some embodiments, the tank body 10 is made of a rigid material, such that the internal volume of the air chamber 11 and the fluid storage chamber 12 will not change. The internal volume of the air chamber 11 may be larger than that of the fluid storage chamber 12, such that the air chamber 11 may adjust the pressure of the fluid storage tank 210 more quickly. In other embodiments, the internal volume of the fluid storage chamber 12 may also be larger than that of the air chamber 11, such that the fluid storage chamber 12 may accommodate more second coolant.

In some embodiments, the air chamber 11 is located above the fluid storage chamber 12, and the adjusting member 20 is located at the top of the tank body 10. Since hot air will move upward, placing the air chamber 11 above the fluid storage chamber 12 prevents the fluid storage chamber 12 from blocking the air chamber 11, such that the adjusting member 20 may release the pressure in the air chamber 11 more quickly. In other embodiments, the fluid storage chamber 12 may also be located at the left, right, or other sides of the air chamber 11. For example, the air chamber 11 may surround the fluid storage chamber 12 to cool the air chamber 11 more quickly.

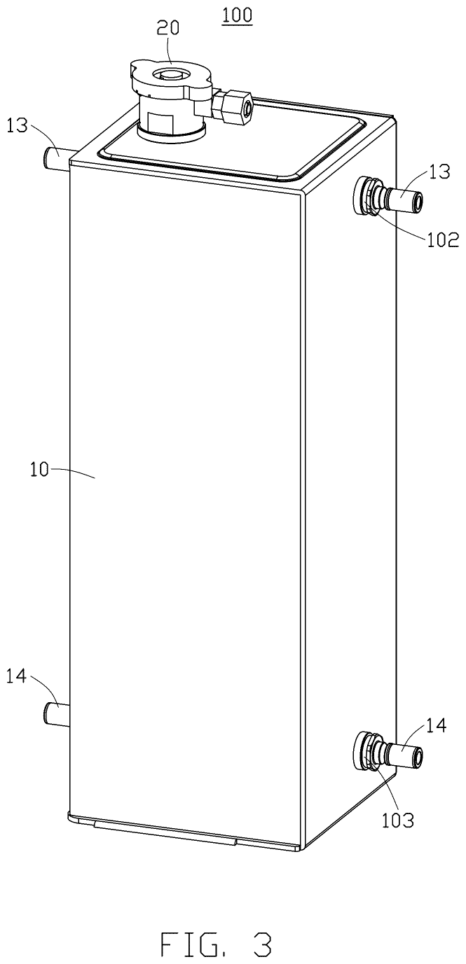

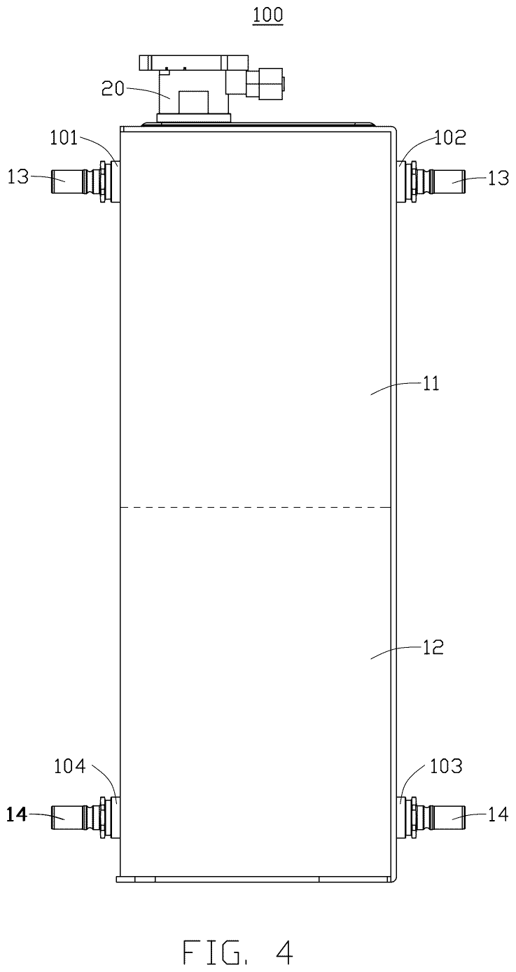

Referring to FIGS. 3 and 4, the tank body 10 further includes a first inlet 101 and a first outlet 102 each connected to the air chamber 11. The first inlet 101 is connected to the fluid storage tank 210, such that the first coolant in the fluid storage tank 210 enters the air chamber 11 through the first inlet 101, thereby reducing the pressure in the fluid storage tank 210. The first outlet 102 is used to discharge the coolant in the air chamber 11. In some embodiments, the first inlet 101 and the second outlet 104 are located at two opposite sidewalls of the tank body 10 and at an upper end of the tank body 10, thereby facilitating the connection of the air chamber 11 to the fluid storage tank 210 and the cooling member 230 through the pipeline 240.

The tank body 10 further includes a second inlet 103 and a second outlet 104 each connected to the fluid storage chamber 12. The fluid storage chamber 12 receives and stores the second coolant through the second inlet 103, thereby supplementing the coolant in the fluid storage chamber 12 and cool the air chamber 11. The second outlet 104 is connected to the fluid storage tank 210, such that the second coolant in the fluid storage chamber 12 may flow into the fluid storage tank 210 through the second outlet 104, thereby reducing the pressure of the fluid storage tank 210 more quickly. In some embodiments, the second inlet 103 and the second outlet 104 are located at two opposite sidewalls of the tank body 10 and at a lower end of the tank body 10, thereby facilitating the connection of the fluid storage chamber 12 to the fluid storage tank 210 and the cooling tank 220 through the pipeline s240. The second coolant enters the fluid storage tank 210 through the pipeline 240 from the lower end of the fluid storage chamber 12 away from the air chamber 11. Thus, the second coolant at the lower end of the fluid storage chamber 12 away from the air chamber 11 will not be affected by the air chamber 11, such that the second coolant supplied to the fluid storage tank 210 will maintain a low temperature, which is beneficial for cooling the fluid storage tank 210.

When the first coolant flows into the fluid storage tank 210, the first coolant in the fluid storage tank 210 expands in volume, and the pressure in the fluid storage tank 210 increases. Then, the high-temperature in the fluid storage tank 210 is forced into the air chamber 11, thereby releasing the pressure of the fluid storage tank 210. The pressure in the fluid storage tank 210 returns to the original value, thereby protecting the fluid storage tank 210. At this time, the pressure in the air chamber 11 is greater than the pressure outside the tank body 10 (in the ambient environment). The adjusting member 20 discharges the air in the air chamber 11 to release the pressure in the air chamber 11. Also, the fluid storage chamber 12 supplements the second coolant into the fluid storage tank 210, and the second coolant may cool the fluid storage tank 210. When the fluid storage tank 210 is cooled, the fluid storage tank 210 may release the pressure therein more quickly, thereby allowing the fluid storage tank 210 to quickly recover to the original state. When the second coolant in the fluid storage chamber 12 is insufficient, the cooling tank 220 may supplement the second coolant into the fluid storage chamber 12.

In some embodiments, the adjusting member 20 is a pressure regulating valve. The pressure regulating valve senses the pressure in the air chamber 11. When the pressure in the air chamber 11 is greater than the pressure in the ambient environment, the pressure regulating valve discharges the air in the air chamber 11 to reduce the pressure in the air chamber 11. When the pressure in the air chamber 11 is less than the pressure in the ambient environment, the pressure regulating valve allows the ambient air to enter the air chamber 11 to increase the pressure in the air chamber 11. Thus, the tank body 10 has no need to adjust the pressure through deformation of a rubber diaphragm, thereby avoiding breakage of the rubber diaphragm after long-time use. Thus, the reliability of the expansion tank 100 is improved.

In some embodiments, referring to FIG. 1, the cooling system 200 further includes a cooling member 230 connected to the first outlet 102. The first coolant in the air chamber 11 may enter the cooling member 230 through the first outlet 102, and the cooling member 230 is used to cool the coolant. In order to recycle the coolant discharged from the first outlet 102, the cooling member 230 is connected to the cooling tank 220, such that the coolant from the cooling member 230 may flow back into the cooling tank 220.

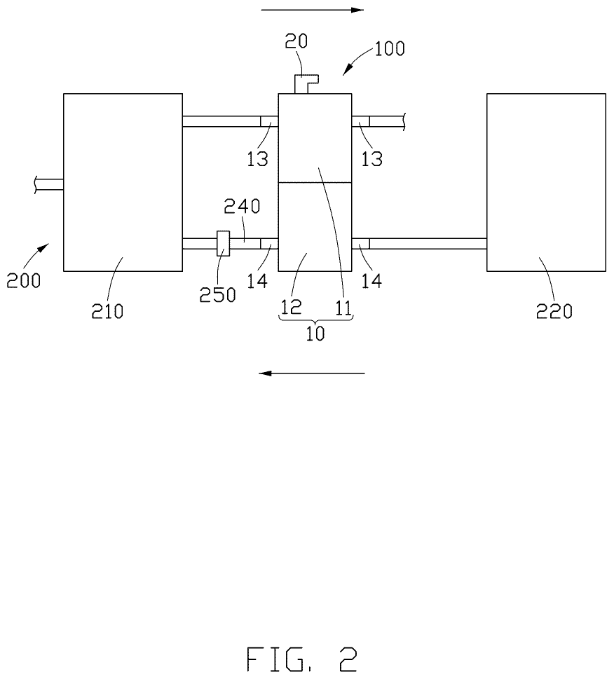

Referring to FIG. 2, in another embodiment, the coolant from the first outlet 102 may also be discharged for disposal.

In some embodiments, the cooling system 200 further includes a valve 250 and a number of pipelines 240. The pipelines 240 connect the fluid storage tank 210 to the first inlet 101, the fluid storage tank 210 to the second outlet 104, and the cooling tank 220 to the second inlet 103, respectively. The valve 250 is installed at the pipeline 240 that connects the fluid storage tank 210 to the second outlet 104. The valve 250 is used to control the flowing direction of the coolant in the pipeline 240 and prevent the first coolant in the fluid storage tank 210 from entering the fluid storage chamber 12. For example, the valve 250 may be a one-way valve.

A valve may also be is installed at the pipeline 240 that connects the fluid storage tank 210 to the first inlet 101. The valve is used to allow the first coolant to flow the fluid storage tank 210 to the air chamber 11, or to prevent the coolant in the fluid storage tank 210 from flowing into the air chamber 11.

Referring to FIG. 1, the first outlet 102 is connected to the cooling member 230 through one pipeline 240, and the cooling member 230 is connected to the cooling tank 220 through one pipeline 240, such that the cooling member 230 can cool the first coolant, and the cooled coolant enters the cooling tank 220 for storage. Valves may also be installed on the pipeline 240 between the first outlet 102 and the cooling member 230, and on the pipeline 240 between the cooling member 230 and the cooling tank 220, which may control the flow of coolant.

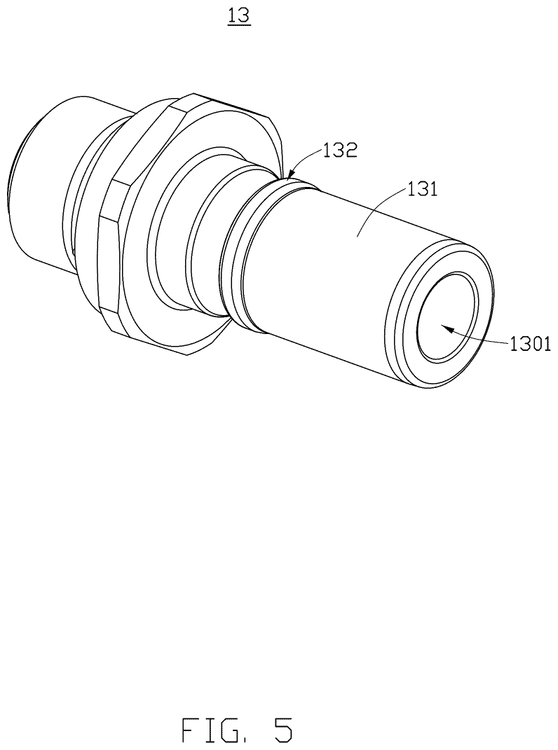

In some embodiments, referring to FIGS. 4 and 5, the expansion tank 100 further includes two first connecting members 13 and two second connecting members 14. Each first connecting member 13 has a first channel 1301. The two first connecting members 13 are connected to the first inlet 101 and the first outlet 102, respectively, such that the first channel 1301 communicates with the air chamber 11. The first connecting member 13 is further plugged into the pipeline 240, that is, the pipeline 240 is connected to the air chamber 11 through the first connecting member 13. The first connecting member 13 may reduce leakage of the coolant at the first inlet 101 or the first outlet 102.

The second connecting member 14 has a second channel (not shown). The two second connecting members 14 are connected to the second inlet 103 and the second outlet 104, respectively, such that the second channel communicates with the fluid storage chamber 12. The second connecting member 14 is further plugged into the pipeline 240, such that the pipeline 240 is connected to the fluid storage chamber 12 through the second connecting member 14. The second connecting member 14 may reduce leakage of the coolant at the second inlet 103 or the second outlet 104.

In some embodiments, the first connecting member 13 includes a main body 131 and a flange 132 connected to the periphery of the main body 131. The first channel 1301 is defined in the main body 131. After the connecting member is plugged into the first connecting member 13, the pipeline 240 is fitted around the periphery of the flange 132. The flange 132 is abutted against the periphery of the pipeline 240 to increase the friction between the pipeline 240 and the first connecting member 13, thereby preventing the pipeline 240 from separating off from the main body 131. The structure of the second connecting member 14 may be the same as that of the first connecting member 13, and will not be repeated.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. An expansion tank applied in a cooling system, the cooling system comprising a fluid storage tank for storing a coolant, the expansion tank comprising:
a tank body comprising an air chamber, a fluid storage chamber, a first inlet, a first outlet, a second inlet, and a second outlet, wherein the air chamber and the fluid storage chamber are separated from each other, each of the first inlet and the first outlet is connected to the air chamber, each of the second inlet and the second outlet is connected to the fluid storage chamber, the first inlet is further connected to the fluid storage tank, thereby allowing the coolant in the fluid storage tank to enter the air chamber through the first inlet to reduce a pressure in the fluid storage tank, the first outlet is configured to discharge the coolant in the air chamber, the fluid storage chamber is configured to receive the coolant after being cooled through the second inlet to cool the air chamber, the second outlet is further connected to the fluid storage tank, thereby allowing the cooled coolant in the fluid storage chamber to be supplemented to the fluid storage tank through the second outlet; and
an adjusting member configured to connect the air chamber to an ambient environment to adjust a pressure in the air chamber.

2. The expansion tank according to claim 1, wherein the air chamber is located gravitationally above the fluid storage chamber, and the adjusting member is located at a top of the air chamber.

3. The expansion tank according to claim 2, wherein the first inlet and the second outlet are located at two opposite surfaces of the tank body.

4. The expansion tank according to claim 1, further comprising two first connecting members, wherein each of the two first connecting members comprises a first channel, the two first connecting members are connected to the first inlet and the first outlet, respectively, such that the first channel communicates with the air chamber, the two first connecting members are configured to plug into two respective pipelines, and one of the two pipelines is connected to the fluid storage tank.

5. The expansion tank according to claim 4, wherein the first connecting member comprises a main body and a flange connected to a periphery of the main body, the first channel is defined in the main body, and the flange is configured to abut against a periphery of the pipeline.

6. The expansion tank according to claim 1, wherein an internal volume of the air chamber is larger than an internal volume of the fluid storage chamber.

7. The expansion tank according to claim 1, wherein an internal volume of the fluid storage chamber is larger than an internal volume of the air chamber.

8. The expansion tank according to claim 1, wherein the adjusting member is a pressure regulating valve.

9. A cooling system comprising:
a fluid storage tank configured for storing a coolant;
a cooling tank configured for storing the coolant after being cooled; and
an expansion tank comprising:
a tank body comprising an air chamber, a fluid storage chamber, a first inlet, a first outlet, a second inlet, and a second outlet, wherein the air chamber and the fluid storage chamber are separated from each other, each of the first inlet and the first outlet is connected to the air chamber, each of the second inlet and the second outlet is connected to the fluid storage chamber, the first inlet is further connected to the fluid storage tank, thereby allowing the coolant in the fluid storage tank to enter the air chamber through the first inlet to reduce a pressure in the fluid storage tank, the first outlet is configured to discharge the coolant in the air chamber, the second inlet is further connected to the cooling tank, such that the fluid storage chamber receives the cooled coolant through the second inlet to cool the air chamber, the second outlet is further connected to the fluid storage tank, thereby allowing the cooled coolant in the fluid storage chamber to be supplemented to the fluid storage tank through the second outlet; and
an adjusting member configured to connect the air chamber to an ambient environment to adjust a pressure in the air chamber.

10. The cooling system according to claim 9, further comprising a cooling member, wherein the cooling member is connected to the first outlet and the cooling tank, such that the coolant in the air chamber enters the cooling member through the first outlet, and the cooling member is configured to cool the coolant and allow the cooled coolant to enter the cooling tank.

11. The cooling system according to claim 9, further comprising a valve and a plurality of pipelines, wherein the plurality of pipelines connect the fluid storage tank to the first inlet, the fluid storage tank to the second outlet, and the cooling tank to the second inlet, the valve is installed at one of the plurality of pipelines connecting the fluid storage tank to the second outlet, and the valve is configured to allow the coolant to flow from the fluid storage tank to the fluid storage chamber.

12. The cooling system according to claim 9, wherein the air chamber is located gravitationally above the fluid storage chamber, and the adjusting member is located at a top of the air chamber.

13. The cooling system according to claim 12, wherein the first inlet and the second outlet are located at two opposite surfaces of the tank body.

14. The cooling system according to claim 9, wherein the expansion tank further comprises two first connecting members, wherein each of the two first connecting members comprises a first channel, the two first connecting members are connected to the first inlet and the first outlet, respectively, such that the first channel communicates with the air chamber, the two first connecting members are configured to plug into the plurality of pipelines.

15. The cooling system according to claim 14, wherein the first connecting member comprises a main body and a flange connected to a periphery of the main body, the first channel is defined in the main body, and the flange is configured to abut against a periphery of the pipeline.

16. The cooling system according to claim 9, wherein an internal volume of the air chamber is larger than an internal volume of the fluid storage chamber.

17. The cooling system according to claim 9, wherein an internal volume of the fluid storage chamber is larger than an internal volume of the air chamber.

18. The cooling system claim 1, wherein the adjusting member is a pressure regulating valve.
